(19) United States
(12) Patent Application Publication
(10) Pub. No.: US 2004/0229442 A1
(43) Pub. Date: Nov. 18, 2004

(54) Method for forming high resistive region in semiconductor device

(76) Inventor: Kyeong Keun Choi, Suwon-Shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/730,295

(22) Filed: Dec. 8, 2003

(30) Foreign Application Priority Data
May 12, 2003 (KR) 2003-29746

(51) Int. Cl. H01L 21/20; H01L 21/76

(52) U.S. Cl. 438/424; 438/421

(57) ABSTRACT

The present invention relates to a method for forming a high resistive region in a semiconductor device. A pattern having the bottom wider in width than the top such as a trench is formed in a region where an inductor will be formed by means of a two-step or multi-step etch processes. While forming an air gap at the corner of the bottom of the trench using a coverage characteristic of an insulating material, the trench is buried with the insulating material to easily form a high resistive region. Therefore, the present invention can minimize reduction in the quality factor (Q reduction) by preventing, by maximum, the eddy current from being generated in the substrate due to the inductor.

### BACKGROUND

1. Field of the Invention

The present invention relates to a method for forming a high resistive region in a semiconductor device and, more particularly, to a method for forming a high resistive region in a semiconductor device capable of reducing the eddy current between elements formed in a semiconductor substrate and the substrate to minimize reduction in the quality factor (Q reduction).

2. Discussion of Related Art

In a CMOS RF technology, RF is lowered to a base band level using direct conversion, etc., thus allowing RF chips to be manufactured even with a common CMOS process. This technology is a nucleus technology to integrate the base band and RF into a single chip, which enables system on chip (SoC) for wireless communication devices to be developed. For system on chip, it is required that a RF integrated circuit be fabricated in which the active element and the passive element are formed on a single semiconductor substrate by means of a batch process. By using components having functions of amplifying a weak signal and converting the frequency when the RF integrated circuit is fabricated, not only the RF system can be miniaturized and lightened but also the number of the components can be significantly reduced, thus resulting in increase in the production yield.

FIG. 1 is a three-dimensional perspective view illustrating an exemplary RF CMOS having an active element and a passive element formed on the same substrate.

As shown in FIG. 1, not only the active element and the passive element but also electrical connections with unit elements are simultaneously formed on the semiconductor substrate by means of a batch process. It is thus possible to accomplish the RF CMOS having a reduced size, high reliability and a uniform characteristic compared to a conventional RF circuit substrate. Further, it has been known that this type of RF CMOS has a low manufacturing cost and a high competitiveness in wireless communication device market since packages for individual components are not required, compared to a case where the RF circuit is formed using individual components. In other words, in order to fabricate the RF circuit in the prior art, the RF circuit substrate in which the active element and the passive element being individual components are mounted on a ceramic substrate, etc. was used. As the wireless systems becomes miniaturized and mass-produced, however, the circuit substrate is replaced with the semiconductor substrate.

As such, the RF CMOS device is classified into the active element and the passive element. The resistor, the inductor and the capacitor are formed in the passive element and a wiring may be formed between the active element and the passive element. In the above, characteristics of the passive element are provided as data that are generated by measuring RF characteristics from a standard device of a defined structure and size, extracting equivalent circuit parameters and inducing characteristic rules. At this time, the inductor has usually a spiral structure. The characteristic of the inductor is varied depending on line width and distance of a metal, the number of a spiral. These characteristics are provided as data that are produced by extracting the equivalent circuit parameters and inducing characteristic rules form the RF CMOS device.

The quality factor (Q) is reduced in the inductor being the passive element due to eddy current, etc. in the RF device. In order to prevent this, the inductor is formed on a high resistive Si substrate, SOI, SOS, quartz substrate of over 10 ohm-cm. This technology, however, has problems that a substrate must be newly purchased, various complicated technologies are needed, etc.

### SUMMARY OF THE INVENTION

The present invention is contrived to solve the aforementioned problems. The present invention is to provide a method for forming a high resistive region in a semiconductor device capable of minimizing reduction in the quality factor (Q reduction) by preventing, by maximum, the eddy current from occurring in the substrate due to an inductor, in such a manner that a pattern having the bottom wider in width than the top such as a trench is formed in a region where the inductor will be formed by performing an etch process of a combination of two-step or multi-step dry etch and wet etches, and the trench is buried with an insulating material to easily form a high resistive region while forming an air gap at the corner of the bottom of the trench using a coverage characteristic of the insulating material.

One aspect of the present invention is to provide a method for forming a high resistive region in a semiconductor device, comprising the steps of: forming a trench, in which a width of a bottom is wider than a top, in a given region of a semiconductor substrate; and burying the trench with an insulating layer while forming empty spaces at both corners of the bottom of the trench, by using a coverage characteristic of an insulating material.

In the aforementioned of a method for forming a high resistive region in a semiconductor device according to another embodiment of the present invention, the step of forming the trench comprises the steps of forming a mask pattern on the semiconductor substrate, etching the semiconductor substrate to a given depth by means of a first etch process, thus forming the trench, forming the trench to a target depth by means of a second etch process in a vertical and a horizontal directions, while forming the trench having the bottom wider in width than the top, and removing the mask pattern. At this time, upon the first etch process, polymer is deposited on the sidewall of the trench while being generated, thus serving as an anti-etch film at the time of the second etch process. Preferably, said first etch process is performed using a dry etch process and the second etch process is performed using a wet etch process. Meanwhile, the first etch process may be performed by applying a power of 300 W to 2000 W in an RIE reactor and using an etch gas containing chlorine. Furthermore, the second etch process may use a mixed solution of HNO₃:HF:H₂O as an etchant.

The insulating layer is formed using a conventional technology. At this time, the insulating layer may be formed using a thin spin on dielectric (SOD) film or a thin CVD film. For example, the CVD film is formed of a TEOS oxide film. The CVD film is deposited by means of the chemical vapor deposition method under a temperature in the range of 300 to 500° C. in the CVD reactor and is buried into the trench while not being formed at both corners of the bottom of the trench due to deposition characteristics, such as the coverage.

Before the trench is buried, a SiN thin film may be deposited on the substrate including the inner surface of the trench.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a three-dimensional perspective view illustrating an exemplary RF CMOS having an active element and a passive element formed on the same substrate; and

FIGS. 2A to 2G are sectional views illustrating the steps of forming a high resistive region in a semiconductor device according to an embodiment of the present invention.

### DETAILED DESCRIPTION OF PREFERRED EMBODIMENTS

The present invention will now be described in detail in connection with preferred embodiments with reference to the accompanying drawings, in which like reference numerals are used to identify the same or similar parts.

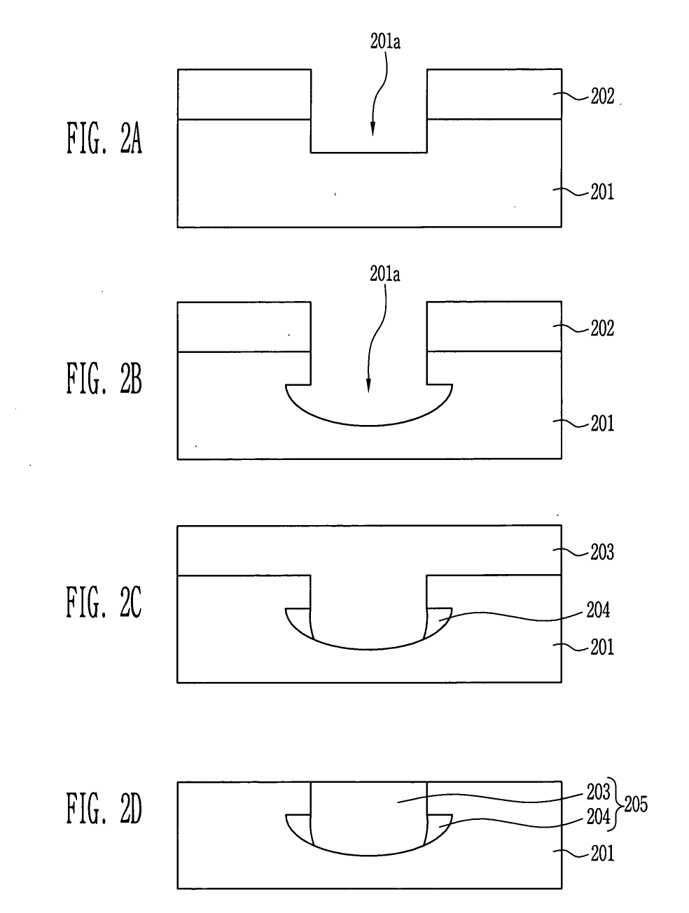

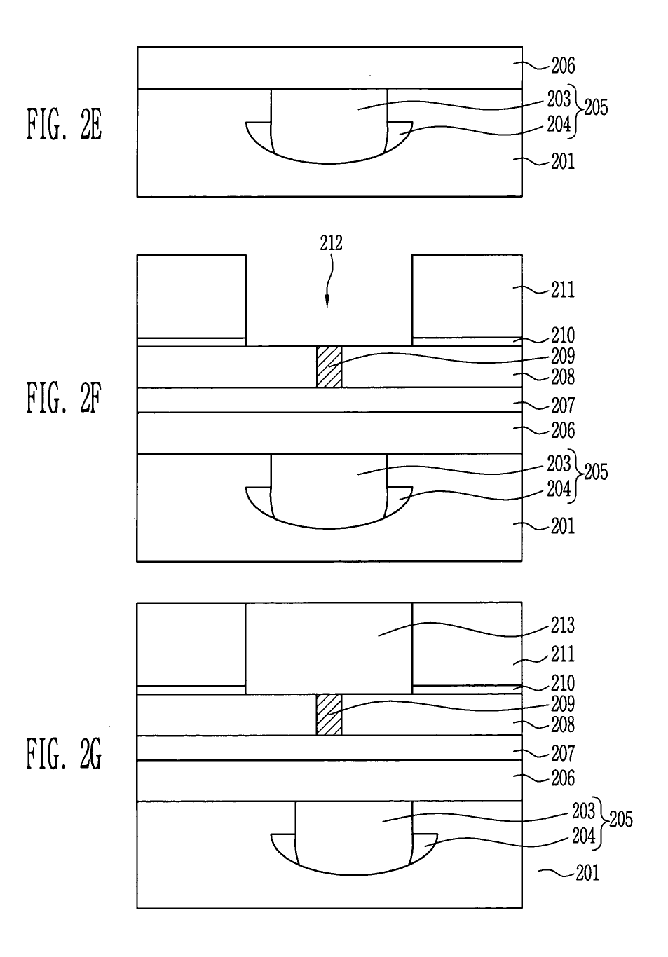

FIGS. 2A to 2G are sectional views illustrating steps of forming a high resistive region in a semiconductor device according to an embodiment of the present invention.

Referring to FIG. 2A a mask pattern 202, in which an isolation region or a region for increasing a resistance value (hereinafter referred to as ‘high resistive region’) is defined, is formed on a semiconductor substrate 201. The semiconductor substrate 201 of the high resistive region is etched by means of a first etch process, thus forming a trench 201a.

If it is the case where a RF integrated circuit having the passive element and the active element including the inductor is implemented on the same substrate, a region in which the inductor will be formed may be defined as a high resistive region so as to prevent the eddy current from generating in the substrate 201 due to the inductor.

In the above, the mask pattern 202 for defining the high resistive region may be formed using a photoresist pattern but may be formed using a stack structure pattern of the pad oxide film and the pad nitride film. At this time, the thickness of the mask pattern 202 may be decided depending on the thickness of the semiconductor substrate 201 of the high resistive region. For example, if the thickness of the semiconductor substrate 201 is 10 μm, the mask pattern 202 may be formed in a thickness of 2 μm to 4 μm considering the etch selectivity between the substrate and the mask pattern.

Meanwhile, the first etch process may be performed using a dry etch process, which etches the semiconductor substrate 201 as much thickness as 4 μm to 6 μm. The dry etch process may be performed by applying a power of 300 W to 2000 W (8 inch wafer basis) in an RIE (reactive ion etch) reactor and using an etch gas containing chlorine (Cl₂). At this time, the etch gas containing Cl₂ may use a gas where Cl₂ of 10 to 300 sccm, Ar of 100 to 1000 sccm and 02 of 5 to 100 sccm are mixed as the etch gas.

By reference to FIG. 2B, a second etch process is performed so that etch is performed in a lateral direction while the high resistive region is more deeply etched. At this time, polymer (not shown) remaining at the sides of the trench 201a, which is generated during the first etch process implemented in FIG. 2A, serves as an anti-etch film, the sides of the trench 201a at the time of the second etch process is rarely etched. For this reason, the width at the bottom of the trench 201a becomes wider than that at the top of the trench 201a. The second etch process may be performed using the etch process and may use a mixed solution of HNO₃: HF:H₂O as an etchant.

Meanwhile, if it is desired to more deeply form the trench, the first etch process and the second etch process are repeatedly performed to form the trench of a target depth.

With reference to FIG. 2C, after removing the mask pattern 202 in FIG. 2B, an insulating layer 203 is formed on the entire structure so that the trench 201a is buried. In this case, if the insulating layer 203 is formed utilizing a coverage characteristic of the insulating layer 203, the insulating layer 203 is not buried into the portions whose width is widened at the bottom of the trench 201a. This causes an empty air layer 204 to be formed.

The insulating layer may be formed using a conventional technology. At this time, the insulating layer may be formed using the thin spin on dielectric (SOD) film or the thin CVD film. For example, the CVD film is formed using a TEOS oxide film. The CVD film is deposited by means of the chemical vapor deposition method under a temperature in the range of 300° C. to 500° C. in the CVD reactor and is buried into the trench while not being formed at both corners of the bottom of the trench due to the deposition characteristic.

In the concrete, for example, if the insulating layer 203 is formed by depositing the TEOS oxide film by means of the chemical vapor deposition method while keeping a temperature in the range of 300° C. to 500° C. in the CVD reactor, the trench 201a can be buried with the insulating layer 203 while forming the air layer 204 using the coverage characteristic of the insulating layer 203.

Meanwhile, before the trench 201a is buried with the insulating layer 203, a SiN thin film (not shown) may be deposited. At this time, it is preferred that the SiN thin film is deposited in a thickness of 200 to 1000 Å. By depositing the thin SiN film, it is possible to more effectively prevent the eddy current from occurring in the substrate 201 due to the inductor.

Referring to FIG. 2D, the insulating layer on the semiconductor substrate 201 is removed by means of the polishing process, thus making the insulating layer 203 left only in the trench 201a. At this time, the polishing process may be performed by a chemical mechanical polishing process. The high resistive region 205 is thus formed. If the inductor is formed on the high resistive region 205, it prevents the eddy current from being generated in the substrate due to the inductor, thus preventing reduction in the quality factor.

Thereafter, the active element and the passive element are formed in the semiconductor substrate 201 by means of a common process. The inductor may be formed in the high resistive region 205. This process will be described below in short by way of an example.

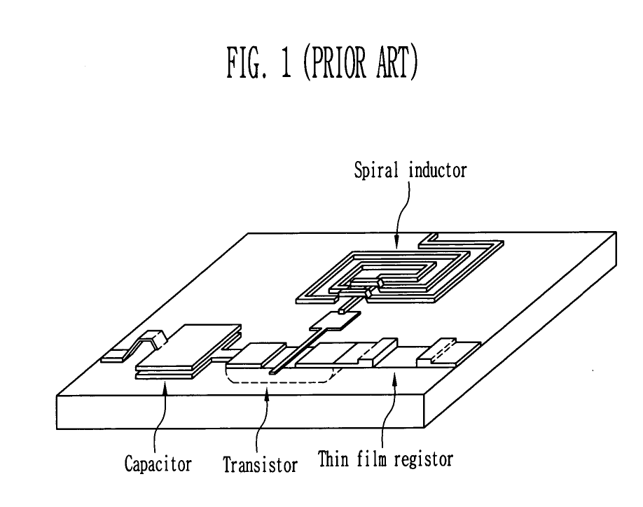

By reference to FIG. 2E the active element (not shown) and the passive element (not shown) are formed on the semiconductor substrate 201 by means of a common process. The active element may include a capacitor or a thin film resistor shown in FIG. 1. The passive element may include the transistor shown in FIG. 1. As such, the first interlayer insulating film 206 is formed on the semiconductor substrate 201 while the active element and the passive element are formed.

With reference to FIG. 2F, a first inductor layer 207 is formed and a second interlayer insulating film 208 is then formed. A given portion of the second interlayer insulating film 208 on the high resistive region 205 is then etched to form a via hole. Next, a conductive material is buried into the via hole to form a via plug 209. Thereafter, after sequentially forming an anti-etch film 209 and a third interlayer insulating film 210, the third interlayer insulating film 210 and the anti-etch film 209 on the high resistive region 205 by means of the etch process, thereby exposing portions of the second interlayer insulating film 208 and the via plug 209. Thereby, a region 212 where the second inductor layer will be formed is defined.

Referring to FIG. 2G, the region from which the third interlayer insulating film 210 and the anti-etch film 209 are removed is buried with a conductive material to form a second inductor layer 213.

As described above, according to the present invention, a trench having the bottom wider in width than the top is formed in a region where an inductor will be formed by means of a two-step etch process. The trench is buried with an insulating material while forming an air gap at the corner of the bottom of the trench using a coverage characteristic of the insulating material. Therefore, the present invention has advantageous effects that not only a high resistive region can be easily formed but also generation of the eddy current in a substrate due to the inductor can be prevented by maximum to minimize the quality factor.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

What is claimed is:

1. A method for forming a high resistive region in a semiconductor device, comprising the steps of:
forming a trench, in which a width of a bottom is wider than a top, in a given region of a semiconductor substrate; and
burying the trench with an insulating layer while forming empty spaces at both corners of the bottom of the trench, by using a coverage characteristic of an insulating material.

2. The method for claim 1, wherein the step of forming the trench comprises the steps of:
forming a mask pattern on the semiconductor substrate;
etching the semiconductor substrate to a given depth by means of a first etch process, thus forming the trench;
forming the trench to a target depth by means of a second etch process in a vertical and a horizontal directions, while forming the trench to have the bottom wider than the top in width; and
removing the mask pattern.

3. The method for claim 2, wherein upon the first etch process, polymer is deposited on the sidewall of the trench while being generated, thus serving as an anti-etch film at the time of the second etch process.

4. The method for claim 3, wherein the first etch process is performed by applying a power in the range of 300 W to 2000 W in an RIE reactor and using an etch gas containing chlorine.

5. The method for claim 3, wherein the second etch process uses a mixed solution of HNO₃:HF:H₂O as an etchant.

6. The method for claim 3, wherein the first etch process and the second etch process are performed repeatedly to form the trench to a target depth.

7. The method for claim 2, wherein the first etch process is performed using a dry etch process and the second etch process is performed using a wet etch process.

8. The method for claim 7, wherein the first etch process is performed by applying a power in the range of 300 W to 2000 W in an RIE reactor and using an etch gas containing chlorine.

9. The method for claim 7, wherein the second etch process uses a mixed solution of HNO₃:HF:H₂O as an etchant.

10. The method for claim 7, wherein the first etch process and the second etch process are performed repeatedly to form the trench to a target depth.

11. The method for claim 2, wherein the first etch process is performed by applying a power in the range of 300 W to 2000 W in a RIE reactor and using an etch gas containing chlorine.

12. The method for claim 11, wherein the first etch process and the second etch process are performed repeatedly to form the trench to a target depth.

13. The method for claim 2, wherein the second etch process uses a mixed solution of HNO₃:HF:H₂O as an etchant.

14. The method for claim 13, wherein the first etch process and the second etch process are performed repeatedly to form the trench to a target depth.

15. The method for claim 2, wherein the first etch process and the second etch process are performed repeatedly to form the trench to a target depth.

16. The method for claim 1, wherein the insulating layer is formed using a TEOS oxide film and is deposited by means of a chemical vapor deposition method under a temperature in the range of 300° C. to 500° C. in a CVD reactor, whereby the insulating layer is not formed at both corners of the bottom of the trench due to a coverage characteristic while being buried into the trench.

17. The method for claim 1, wherein the insulating layer is formed using a SOD or SOG oxide film and is buried into the trench, while the insulating layer is not formed at both corners of the bottom of the trench due to a coverage characteristic of a spin coating oxide film.

18. The method for claim 1, before the trench is buried, further comprising the step of depositing a SiN thin film on the substrate including an inner surface of the trench.
